(19) United States
(12) Patent Application Publication
(10) Pub. No.: US 2024/0196591 A1
(43) Pub. Date: Jun. 13, 2024

(54) MEMORY DEVICE USING SEMICONDUCTOR ELEMENT

(71) Applicant: Unisantis Electronics Singapore Pte. Ltd., Singapore (SG)

(72) Inventors: Masakazu KAKUMU, Tokyo (JP); Koji SAKUI, Tokyo (JP); Nozomu HARADA, Tokyo (JP)

(21) Appl. No.: 18/537,189

(22) Filed: Dec. 12, 2023

(30) Foreign Application Priority Data
Dec. 13, 2022 (WO) PCT/JP2022/045904

(51) Int. Cl. H10B 12/00; G11C 11/404; G11C 11/4096

(52) U.S. Cl. CPC H10B 12/20; G11C 11/404; G11C 11/4096

(57) ABSTRACT

A memory device includes an n-layer 3a formed on a p-layer 1 of a substrate; an n-layer 3b extending in a vertical direction with a columnar p-layer 4 placed thereon; an insulating layer 2; a gate insulating layer 5; a gate conductor layer 22; an insulating layer 6; and a MOSFET made up of a p-layer 8, a gate insulating layer 9, n+ layers 7a and 7b, and a gate conductor layer 10. The n+ layers 7a and 7b, the gate conductor layers 5 and 10, and n-layer 3a are connected to a source line, bit line, plate line, and word line, and control line, respectively. Data retention operation is performed by controlling voltages applied to the respective layers to hold positive hole groups generated in the MOSFET, and data erase operation is performed to remove positive holes accumulated in the p-layer.

### CROSS-REFERENCE TO RELATED APPLICATIONS

This application claims priority to PCT/JP2022/045904, filed Dec. 13, 2022, the entire content of which is incorporated herein by reference.

### BACKGROUND OF THE INVENTION

### Field of the Invention

The present invention relates to a memory device using a semiconductor element.

### Description of the Related Art

In recent years, in LSI (large scale integration) technology development, there have been demands for greater packaging density, higher performance, lower power consumption, and higher functionality of memory devices using semiconductor elements.

Functionality enhancement and density growth of memory devices that use semiconductor elements are under way. There is a DRAM (dynamic random access memory; see, for example, H. Chung, H. Kim, H. Kim, K. Kim, S. Kim, K. W. Song, J. Kim, Y. C. Oh, Y. Hwang, H. Hong, G. Jin, and C. Chung: “4F2 DRAM Cell with Vertical Pillar Transistor (VPT),” 2011 Proceeding of the European Solid-State Device Research Conference, (2011)) connected with a capacitor, using an SGT (surrounding gate transistor; see Japanese Patent Laid-Open No. 2-188966 and Hiroshi Takato, Kazumasa Sunouchi, Naoko Okabe, Akihiro Nitayama, Katsuhiko Hieda, Fumio Horiguchi, and Fujio Masuoka: IEEE Transaction on Electron Devices, Vol.38, No. 3, pp. 573-578 (1991)) as a select transistor, a PCM (phase change memory; see, for example, H. S. Philip Wong, S. Raoux, S. Kim, Jiale Liang, J. R. Reifenberg, B. Rajendran, M. Asheghi and K. E. Goodson: “Phase Change Memory,” Proceeding of IEEE, Vol.98, No 12, December, pp. 2201-2227 (2010)) connected with a variable resistance element, an RRAM (resistive random access memory; see, for example, K. Tsunoda, K.Kinoshita, H. Noshiro, Y. Yamazaki, T. Iizuka, Y. Ito, A. Takahashi, A. Okano, Y. Sato, T. Fukano, M. Aoki, and Y. Sugiyama: “Low Power and high Speed Switching of Ti-doped NiO ReRAM under the Unipolar Voltage Source of less than 3V,” IEDM (2007)), and an MRAM (magneto-resistive random access memory; see, for example, W. Kang, L. Zhang, J. Klein, Y. Zhang, D. Ravelosona, and W. Zhao: “Reconfigurable Codesign of STT-MRAM Under Process Variations in Deeply Scaled Technology,” IEEE Transaction on Electron Devices, pp. 1-9 (2015)) that varies resistance by changing an orientation of a magnetic spin using a current.

There is also a capacitorless DRAM memory cell made up of a single MOS transistor (see M. G. Ertosun, K. Lim, C. Park, J. Oh, P. Kirsch, and K. C. Saraswat: “Novel Capacitorless Single-Transistor Charge-Trap DRAM (1T CT DRAM) Utilizing Electron,” IEEE Electron Device Letter, Vol. 31, No.5, pp. 405-407 (2010); J. Wan, L. Rojer, A. Zaslavsky, and S. Critoloveanu: “A Compact Capacitor-Less High-Speed DRAM Using Field Effect-Controlled Charge Regeneration,” Electron Device Letters, Vol. 35, No. 2, pp. 179-181 (2012); Takashi Ohasawa and Takeshi Hamamoto, “Floating Body Cell—a Novel Body Capacitorless DRAM Cell”, Pan Stanford Publishing (2011); T. Shino, N. Kusunoki, T. Higashi, T. Ohsawa, K. Fujita, K. Hatsuda, N. Ikumi, F. Matsuoka, Y. Kajitani, R. Fukuda, Y. Watanabe, Y. Minami, A. Sakamoto, J. Nishimura, H. Nakajima, M. Morikado, K. Inoh, T. Hamamoto, A. Nitayama: “Floating Body RAM Technology and its Scalability to 32 nm Node and Beyond,” IEEE IEDM (2006); and E. Yoshida and T.Tanaka: “A Design of a Capacitorless 1T-DRAM Technology Cell Gate-Induced Drain-Leakage (GIDL) Current for Low-Power and High-Speed Embedded Memory,” IEEE IEDM (2003)). For example, out of positive hole groups and electron groups generated in a channel by impact ionization phenomenon using a source-drain current of an N-channel MOS transistor, with some or all of the positive hole groups being held in the channel, logical storage data of “1” is written. Then the positive hole groups are removed from the channel and logical storage data of “0” is written. Challenges for the memory cell are to correct reductions in an operating margin caused by fluctuations in a floating body channel voltage and correct reductions in data retention characteristics caused by some positive hole groups, which are a signal charge accumulated in the channel, being removed.

There is also a twin-transistor MOS transistor memory element obtained by forming one memory cell on an SOI layer using two MOS transistors (see, for example, US2008/0137394 A1, US2003/0111681 A1, and F. Morishita, H. Noda, I. Hayashi, T. Gyohten, M. Oksmoto, T. Ipposhi, S. Maegawa, K. Dosaka, and K. Arimoto: “Capacitorless Twin-Transistor Random Access Memory (TTRAM) on SOI,” IEICE Trans. Electron., Vol. E90-c., No. 4 pp. 765-771 (2007)). In such a memory element, an n+ layer which is to become a source or drain to separate floating body channels of the two MOS transistors is formed in contact with an insulating layer located on a side of a substrate. In the memory cell again, positive hole groups, which are a signal charge are accumulated in the channel of one MOS transistor, and consequently, a challenge for the memory cell is to correct reductions in an operating margin as with the above-mentioned memory cell made up of a single MOS transistor or correct reductions in data retention characteristics caused by some positive hole groups, which are a signal charge accumulated in the channel, being removed.

There is also a memory cell made up of a capacitorless MOS transistor such as shown in FIGS. 8A to 8D (see US2008/0137394 A1 and K. Sakui, N. Harada, “Dynamic Flash Memory with Dual Gate Surrounding Gate Transistor (SGT),” Proc. IEEE IMW, pp. 72-75(2021)). This is a dynamic flash memory. As shown in FIG. 8A, there is a floating body semiconductor base body 102 on a SiO2 layer 101 of an SOI substrate. There are an n+ layer 103 to be connected to a source line and an N+ layer 104 to be connected to a bit line BL, on opposite ends of the floating body semiconductor base body 102. There are a first gate insulating layer 109a joined to the n+ layer 103, covering the floating body semiconductor base body 102 and a second gate insulating layer 109b joined to an n+ layer 104, covering the floating body semiconductor base body 102. There are a first gate conductor layer 105a joined to a plate line PL, covering the first gate insulating layer 109a and a second gate conductor layer 105b joined to a word line WL, covering the second gate insulating layer 109b. There is an insulating layer 110 between the first gate conductor layer 105a and the second gate conductor layer 105b. Consequently, a memory cell 111 of a DFM is formed. Note that the source line SL may be connected to the n+ layer 104 with the bit line BL being connected to the n+ layer 103.

As shown in FIG. 8A, for example, by applying a zero voltage to the n+ layer 103, and a positive voltage to the n+ layer 104, a first N-channel MOS transistor region made up of the floating body semiconductor base body 102 covered with the first gate conductor layer 105a is operated in a saturation region and a second N-channel MOS transistor region made up of the floating body semiconductor base body 102 covered with the second gate conductor layer 105b is operated in a linear region. As a result, no pinch-off point exists in the second N-channel MOS transistor region and an inversion layer 107b is formed on an entire surface in contact with the second gate insulating layer 109b. The inversion layer 107b formed on an underside of the second gate conductor layer 105b connected with the word line WL operates as a virtual drain of the first N-channel MOS transistor region. As a result, an electric field is maximized and an impact ionization phenomenon occurs in a boundary region of a channel region between the first N-channel MOS transistor region and the second N-channel MOS transistor region. Then, as shown in FIG. 8B, out of positive hole groups and electron groups generated by the impact ionization phenomenon, the electron groups are removed from the floating body semiconductor base body 102 and some or all of the positive hole groups 106 are held in the floating body semiconductor base body 102. Consequently, a memory write operation is performed.

Then, as shown in FIG. 8C, for example, by applying a positive voltage to the plate line PL, a zero voltage to the word line WL and the bit line BL, and a negative voltage to the source line SL, the positive hole groups 106 are removed from the floating body semiconductor base body 102, thereby performing an erase operation. This state becomes “0” in terms of the logical storage data. Then, during data read, if the voltage to be applied to the first gate conductor layer 105a joined to the plate line PL is set higher than a threshold voltage at a time when the logical storage data is “1” and lower than a threshold voltage at a time when the logical storage data is “0,” the property that no current flows even if the voltage of the word line WL is increased in reading the logical storage data of “0” is obtained as shown in FIG. 8D. This property makes it possible to increase the operating margin more greatly than in the case of a memory cell made up of a capacitorless MOS transistor. In this memory cell, because channels in the first and second N-channel MOS transistor regions that use, as gates, the first gate conductor layer 105a joined to the plate line PL and the second gate conductor layer 105b joined to the word line WL are joined together via the floating body semiconductor base body 102, voltage fluctuations of the floating body semiconductor base body 102 occurring when a selection pulse voltage is applied to the word line WL are reduced greatly. This greatly remedies the problem of the reduced operating margin in the memory cell described above or the problem of the reduced data retention characteristics caused by some positive hole groups, which are a signal charge accumulated in the channel, being removed. Further characteristics improvements in the present memory element are expected in the future.

An object of the present invention is to provide a memory device that uses a semiconductor element that allows a dynamic flash memory, which is a memory device, to stably write, erase, and read memory information.

### SUMMARY OF THE INVENTION

To solve the above problem, according to a first aspect of the present invention, there is provided a memory device that uses a semiconductor element, the memory device comprising: a substrate; a first semiconductor layer placed on the substrate; a first impurity layer placed on part of a surface of the first semiconductor layer; a second impurity layer extending in a vertical direction by being placed in contact with the first impurity layer; a second semiconductor layer extending in the vertical direction by being placed in contact with a columnar part of the second impurity layer; a first insulating layer covering part of the first semiconductor layer and part of the second impurity layer; a first gate insulating layer surrounding the second impurity layer and the second semiconductor layer by being placed in contact with the first insulating layer; a first gate conductor layer placed in contact with the first insulating layer and the first gate insulating layer; a second insulating layer formed in contact with the first gate conductor layer and the first gate insulating layer; a third semiconductor layer placed in contact with the second semiconductor layer; a second gate insulating layer partially or entirely surrounding an upper part of the third semiconductor layer; a second gate conductor layer partially or entirely covering an upper part of the second gate insulating layer; a third impurity layer and a fourth impurity layer placed in contact with a lateral surface of the third semiconductor layer located on an outer side of one end of the second gate conductor layer in a horizontal direction in which the third semiconductor layer extends; a first interconnecting conductor layer connected to the third impurity layer; a second interconnecting conductor layer connected to the fourth impurity layer; a third interconnecting conductor layer connected to the second gate conductor layer; a fourth interconnecting conductor layer connected to the first gate conductor layer; and a fifth interconnecting conductor layer connected to the first impurity layer, wherein a memory write operation is performed by controlling voltages applied to the first interconnecting conductor layer, the second interconnecting conductor layer, the third interconnecting conductor layer, the fourth interconnecting conductor layer, and the fifth interconnecting conductor layer and performing an operation of generating electron groups and positive hole groups in the third semiconductor layer and the second semiconductor layer, by an impact ionization phenomenon or a gate induced drain leakage current using a current passed between the third impurity layer and the fourth impurity layer, an operation of removing the generated electron groups or positive hole groups whichever are minority carriers in the third semiconductor layer and the second semiconductor layer, and an operation of causing part or all of the electron groups or positive hole groups whichever are majority carriers in the third semiconductor layer and the second semiconductor layer to remain in the third semiconductor layer and the second semiconductor layer, and a memory erase operation is performed by controlling voltages applied to the first interconnecting conductor layer, the second interconnecting conductor layer, the third interconnecting conductor layer, the fourth interconnecting conductor layer, and the fifth interconnecting conductor layer, and extracting the electron groups or the positive hole groups whichever are majority carriers remaining in the second semiconductor layer or the third semiconductor layer from at least one location in the first impurity layer, the second impurity layer, the third impurity layer, and the fourth impurity layer by recombining the electron groups or the positive hole groups with majority carriers in the first impurity layer, the second impurity layer, the third impurity layer, and the fourth impurity layer.

According to a second aspect of the present invention, in the first aspect, the first interconnecting conductor layer connected to the third impurity layer is a source line, the second interconnecting conductor layer connected to the fourth impurity layer is a bit line, the third interconnecting conductor layer connected to the second gate conductor layer is a word line, the fourth interconnecting conductor layer connected to the first gate conductor layer is a plate line, and the fifth interconnecting conductor layer is a control line, and the memory write operation and the memory erase operation are performed by applying voltages to the source line, the bit line, the plate line, the word line, and the control line, respectively.

According to a third aspect of the present invention, in the first aspect, during the memory write operation, voltages are applied such that a potential difference is produced between the third and fourth impurity layers, and when majority carriers in the second semiconductor layer are positive holes, a positive voltage is applied to the second gate conductor layer; and when majority carriers in the second semiconductor layer are electrons, a negative voltage is applied to the second gate conductor layer and a voltage of a different polarity from the second gate conductor layer or a voltage of 0 V is applied to the first gate conductor layer.

According to a fourth aspect of the present invention, in the first aspect, during the memory erase operation, a voltage of a different polarity from the time when the memory write operation or a voltage of 0 V is applied to the first gate conductor layer.

According to a fifth aspect of the present invention, in the first aspect, during a memory read operation, a voltage of a same polarity as during the memory write operation or a voltage of 0 V is applied to the first gate conductor layer, and voltages are applied such that a potential difference is produced between the third and fourth impurity layers and a voltage of a same polarity as during the memory write operation is applied to the second gate conductor layer.

According to a sixth aspect of the present invention, in the first aspect, during a memory wait operation, a voltage of a different polarity from a voltage applied during the memory write operation, or a voltage of 0 V is applied to the first gate conductor layer and the second gate conductor layer.

According to a seventh aspect of the present invention, in the first aspect, a threshold of a MOS transistor made up of the third semiconductor layer, the second impurity layer, the third impurity layer, the second gate insulating layer, and the second gate conductor layer before operation is adjusted by changing a voltage applied to the first gate conductor layer.

According to an eighth aspect of the present invention, in the first aspect, majority carriers in the first impurity layer are different form majority carriers in the first semiconductor layer.

According to a ninth aspect of the present invention, in the first aspect, majority carriers in the second impurity layer are different form majority carriers in the first semiconductor layer.

According to a tenth aspect of the present invention, in the first aspect, majority carriers in the second semiconductor layer are same as majority carriers in the first semiconductor layer.

According to an eleventh aspect of the present invention, in the first aspect, majority carriers in the third impurity layer and the fourth impurity layer are same as majority carriers in the first impurity layer.

According to a twelfth aspect of the present invention, in the first aspect, the second impurity layer is lower in concentration than the third impurity layer and the fourth impurity layer.

According to a thirteenth aspect of the present invention, in the first aspect, a vertical distance from a bottom of the third semiconductor layer to an upper part of the second impurity layer is shorter than a vertical distance from the bottom of the third semiconductor layer to a bottom of the first gate conductor layer.

According to a fourteenth aspect of the present invention, in the first aspect, a bottom of the first impurity layer is located deeper than a bottom of the first insulating layer, and the first impurity layer is shared by a plurality of cells.

According to a fifteenth aspect of the present invention, in the first aspect, an upper surface of the second impurity layer is located shallower than an upper surface of the first insulating layer.

### BRIEF DESCRIPTION OF THE DRAWINGS

FIG. 1A is a diagram showing a sectional structure of a memory device using a semiconductor element according to a first embodiment and FIG. 1B is a bird's-eye view of the memory device.

FIGS. 2A, 2B and 2C are diagrams for explaining accumulation of positive hole carriers as well as a cell current, during a write operation of the memory device using the semiconductor element according to the first embodiment.

FIG. 3 is a diagram for explaining operation waveforms applied during the write operation of the memory device using the semiconductor element according to the first embodiment.

FIGS. 4A, 4B and 4C are diagrams for explaining an erase operation of the memory device using the semiconductor element according to the first embodiment.

FIG. 5 is a diagram for explaining operation waveforms applied during the erase operation of the memory device using the semiconductor element according to the first embodiment.

FIG. 6 is a diagram for explaining operation waveforms applied during a read operation of the memory device using the semiconductor element according to the first embodiment.

FIGS. 7A and 7B are sectional structures of additional examples of the memory device using the semiconductor element according to the first embodiment.

FIGS. 8A, 8B, 8C and 8D are diagrams showing sectional structures and operation of a dynamic flash memory device according to a conventional example.

### DETAILED DESCRIPTION OF THE PREFERRED EMBODIMENT

A structure and a drive method of a memory device using a semiconductor element according to an embodiment of the present invention as well as behavior of accumulated carriers in the memory device will be described below with reference to the drawings.

### First Embodiment

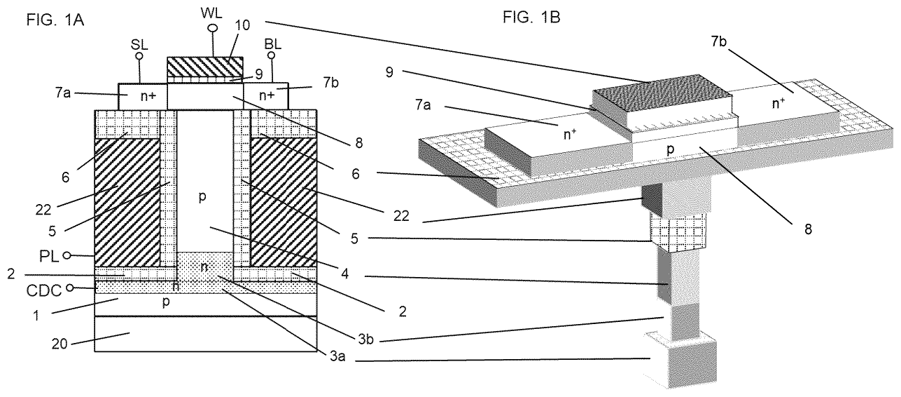

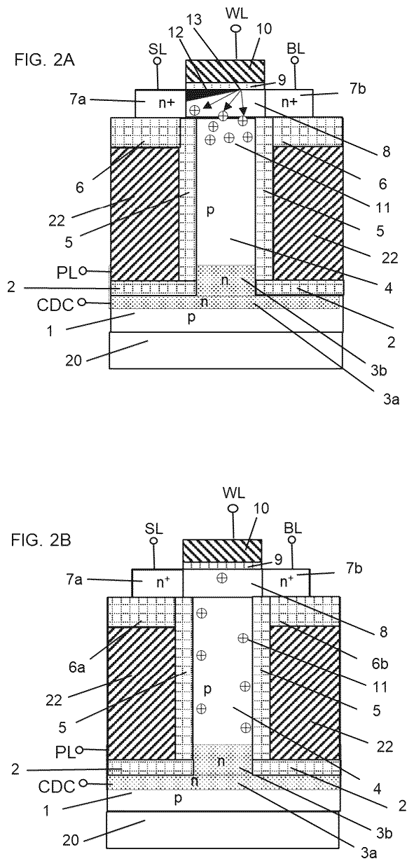

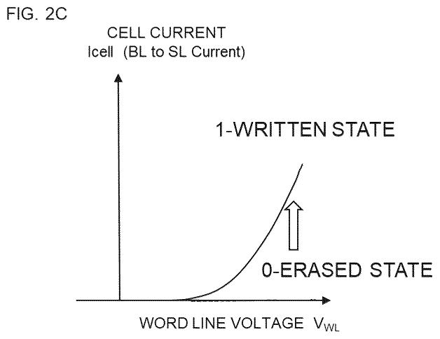

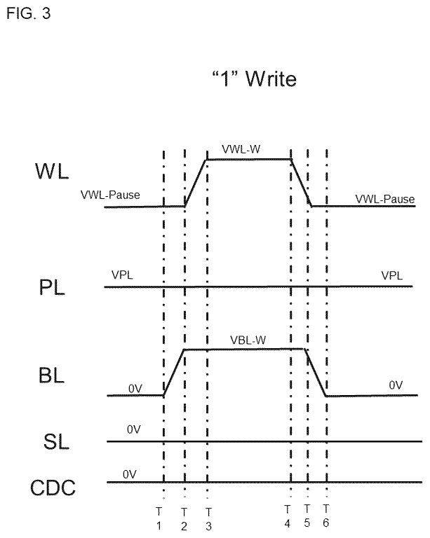

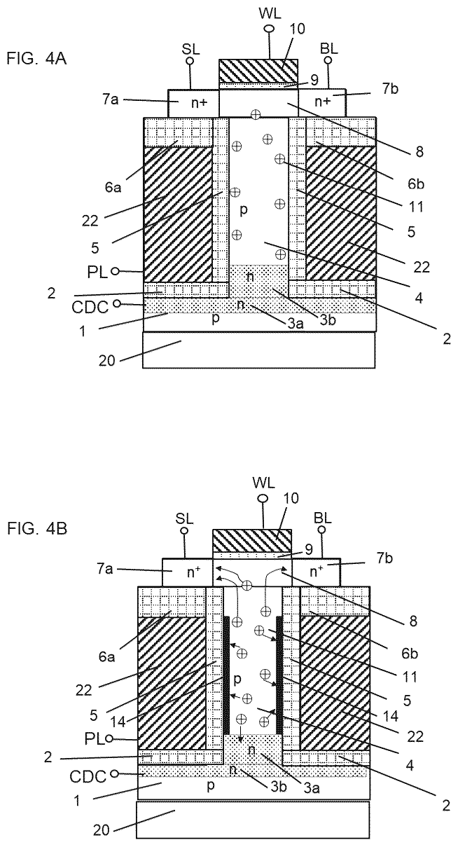

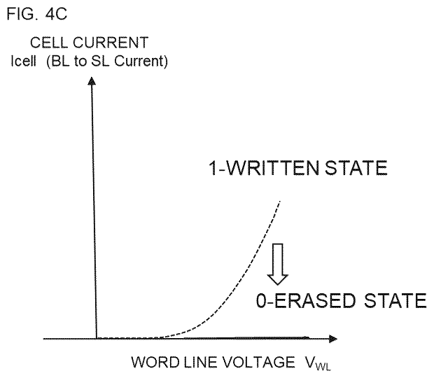

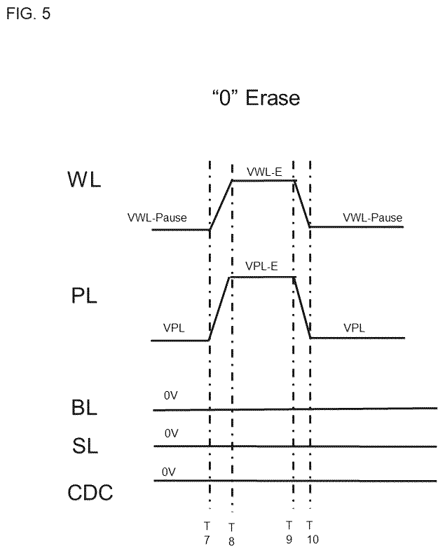

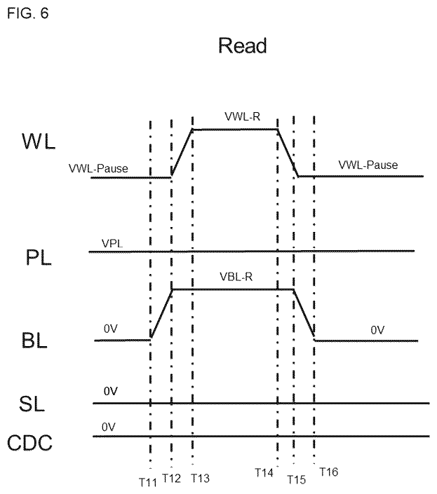

A cell structure of a memory that uses a semiconductor element according to the present embodiment will be described using FIGS. 1A to 6. The cell structure of the memory that uses the semiconductor element according to the present embodiment will be described using FIGS. 1A and 1B, a write mechanism and carrier behavior of the memory cell that uses the semiconductor element will be described using FIGS. 2A to 2C, operation waveforms applied during a memory write operation will be described using FIG. 3, a mechanism of a data erase operation will be described using FIGS. 4A to 4C, operation waveforms applied during a memory erase operation will be described using FIG. 5, and operation waveforms applied during a memory read operation will be described using FIG. 6.

A vertical sectional structure of the memory device using the semiconductor element according to the first embodiment of the present invention is shown in FIG. 1A. A silicon p-layer 1 (which is an example of a “first semiconductor layer” described in Claims) containing acceptor impurities and having a p conductivity type is placed on a substrate 20 (which is an example of a “substrate” described in Claims). A semiconductor having an n-layer 3a (which is an example of a “first impurity layer” described in Claims) containing donor impurities is placed in contact with the p-layer 1. In contact with part of the n-layer 3a, a semiconductor having a columnar n-layer 3b (which is an example of a “second impurity layer” described in Claims) containing donor impurities and erected in a vertical direction is placed. Furthermore, a columnar p-layer 4 (which is an example of a “second semiconductor layer” described in Claims) rectangular in a horizontal section and containing acceptor impurities is placed on top of the n-layer 3b. A first insulating layer 2 (which is an example of a “first insulating layer” described in Claims) is placed covering part of the n-layer 3a and n-layer 3b, and a first gate insulating layer 5 (which is an example of a “first gate insulating layer” described in Claims) is placed in contact with the first insulating layer 2, covering part of the p-layer 4. Besides, a first gate conductor layer 22 (which is an example of a “first gate conductor layer” described in Claims) is placed in contact with the first insulating layer 2 and the first gate insulating layer 5. A second insulating layer 6 (which is an example of a “second insulating layer” described in Claims) is placed in contact with the gate insulating layer 5 and the gate conductor layer 22. A p-layer 8 (which is an example of a “third semiconductor layer” described in Claims) containing acceptor impurities is placed in contact with the p-layer 4.

FIG. 1B shows a bird's-eye view of a memory cell structure according to the present embodiment. In FIG. 1B, for ease of understanding, the n-layer 3a, the n-layer 3b, the p-layer 4, an n+ layer 7a, an n+ layer 7b, the p-layer 8, the gate insulating layer 5, the gate conductor layer 22, a gate insulating layer 9, and a gate conductor layer 10 are shown after removing the p-layer 1 and the first insulating layer 2. Note that the second gate insulating layer 9 and the second gate conductor layer 10 are illustrated by being shifted slightly from the p-layer 8 for ease of understanding.

The n+ layer 7a (which is an example of a “third impurity layer” described in Claims) containing a high concentration of donor impurities is placed on one side of the p-layer 8 (hereinafter a semiconductor region containing a high concentration of donor impurities will be referred to as an “n+ layer”). The n+ layer 7b (which is an example of a “fourth impurity layer” described in Claims) is placed on the side opposite the n+ layer 7a.

The second gate insulating layer 9 (which is an example of a “second gate insulating layer” described in Claims) is placed on an upper surface of the p-layer 8. The gate insulating layer 9 is placed in contact with or in proximity to the n+ layers 7a and 7b. In the vertical direction, being in contact with the gate insulating layer 9, the second gate conductor layer 10 (which is an example of a “second gate conductor layer” described in Claims) is placed on the opposite side of the gate insulating layer 9 form the p-layer 8.

This results in formation of a memory device using a semiconductor element made up of the substrate 20, the p-layer 1, the insulating layer 2, the gate insulating layer 5, the gate conductor layer 22, the insulating layer 6, the n-layer 3a, the n-layer 3b, the p-layer 4, the n+ layer 7a, the n+ layer 7b, the p-layer 8, the gate insulating layer 9, and the gate conductor layer 10. The n+ layer 7a is connected to a source line SL (which is an example of a “source line” described in Claims), which is a first interconnecting conductor layer, the n+ layer 7b is connected to a bit line BL (which is an example of a “bit line” described in Claims), which is a second interconnecting conductor layer, the gate conductor layer 10 is connected to a word line WL (which is an example of a “word line” described in Claims), which is a third interconnecting conductor layer, the gate conductor layer 22 is connected to a plate line PL (which is an example of a “plate line” described in Claims), which is a fourth interconnecting conductor layer, and the n-layer 3a is connected to a control line CDC (which is an example of a “control line” described in Claims), which is a fifth interconnecting conductor layer. By manipulating voltages applied to the source line SL, the bit line BL, the plate line PL, the word line WL, and the control line CDC, the memory is operated. Hereinafter the memory device will be referred to as a dynamic flash memory.

In the actual memory device according to the present embodiment, a dynamic flash memory cell is placed alone on the substrate 20 or a plurality of the dynamic flash memory cells are placed two-dimensionally on the substrate 20.

Whereas the p-layer 1 is described as being a p-type semiconductor in FIGS. 1A and 1B, impurities may have concentration profiles. The impurity concentrations in the n-layer 3a, the n-layer 3b, the p-layer 4, and the p-layer 8 may also have profiles. The impurity concentrations and profiles in the p-layer 4 and the p-layer 8 may be set independently. The p-layer 4 and the p-layer 8 may be formed of different semiconductor material layers. Cross-sections of the p-layer 4 may have the same shape on bonding faces of the p-layer 4 and the p-layer 8 in planar view. Besides, an LDD (highly doped drain) may be provided between the p-layer 8 and the n+ layers 7a and 7b.

Whereas the first semiconductor layer 1 is a p-type semiconductor in FIGS. 1A and 1B, even if a p-well is formed on the substrate 20 made up of an n-type semiconductor substrate and the memory cell of the present invention is placed using the p-well as the first semiconductor layer 1, the memory cell will operate as a dynamic flash memory.

Whereas the n-layer 3a and the n-layer 3b are shown separately in FIGS. 1A and 1B, the n-layer 3a and the n-layer 3b may be a continuous semiconductor layer. Therefore, even though a boundary line between the n-layer 3a and the n-layer 3b is illustrated as coinciding with a bottom of the insulating layer 2 in FIGS. 1A and 1B, the boundary line does not necessarily have to coincide with the bottom of the insulating layer 2 as long as a bottom of the n-layer 3a is located deeper than a bottom of the gate conductor layer 22 and the upper part of the n-layer 3b is located shallower than the bottom of the gate conductor layer 22. Also whereas the n-layer 3a is formed on an entire surface of the p-layer 1 in FIGS. 1A and 1B, there is no need to form the n-layer 3a on the entire surface as long as the n-layer 3a exists under the memory cell. Furthermore, the n-layer 3a may be formed by an n-well in the p-layer 1. Note that hereinafter the n-layer 3a and the n-layer 3b may be collectively referred to as the n-layers 3.

Whereas the insulating layer 2 and the gate insulating layer 5 are shown separately in FIGS. 1A and 1B, the insulating layer 2 and the gate insulating layer 5 may be formed integrally. Hereinafter the insulating layer 2 and the gate insulating layer 5 will also be referred to together as the gate insulating layer 5.

Whereas the third semiconductor layer 8 is a p-type semiconductor in FIGS. 1A and 1B, the third semiconductor layer 8 may be any of the p-type, n-type, and i-type depending on the majority carrier concentration of the p-layer 4, the thickness of the third semiconductor layer 8, the material and thickness of the gate insulating layer 9, and the material of the gate conductor layer 10.

Whereas a bottom of the p-layer 8 and an upper surface of the insulating layer 6 are illustrated as coinciding with each other in FIGS. 1A and 1B, an interface between the p-layer 4 and the p-layer 8 does not need to coincide with the upper surface of the insulating layer 6 as long as the p-layer 4 and the p-layer 8 are in contact with each other and a bottom of the p-layer 4 is deeper than a bottom of the insulating layer 6.

The substrate 20 may be made of any material such as an insulator, a semiconductor, or a conductor as long as the material can support the p-layer 1.

The first to fifth interconnecting conductor layers may be multi-layered as long as the layers do not contact one another.

The gate insulating layers 5 and 9 may be made of any insulating film used in a normal MOS process, such as a SiO2 film, a SiON film, a HfSiON film, or a SiO2/SiN laminate film.

The first gate conductor layer 22 may be formed, for example, of a metal such as W, Pd, Ru, Al, TiN, TaN, or WN; a nitride of the metal; an alloy thereof (including silicides); a laminated structure such as TiN/W/TaN; or a semiconductor doped at high concentration as long as a potential of part of the memory cell can be changed via the gate insulating layer 5, the second gate conductor layer 10, or the gate insulating layer 9.

The vertical sectional structure of the memory cell, which has been described as being rectangular on the plane of the paper in FIGS. 1A and 1B, may be trapezoidal or polygonal. Besides, the cross-sectional shape of the p-layer 4 may be circular in planar view.

In FIGS. 1A and 1B, the first gate conductor layer 22 may surround the entire p-layer 4 or cover part of the p-layer 4 in planar view. The first gate conductor layer 22 may be divided into multiple parts in planar view. Alternatively, the first gate conductor layer 22 may be divided into multiple parts in the vertical direction. Whereas in sectional structure, the first gate conductor layers 22 exist on opposite sides of the p-layer 4 in FIGS. 1A and 1B, the dynamic flash memory can operate if the first gate conductor layer 22 exists on either side of the p-layer 4.

When p+ layers (hereinafter a semiconductor region containing a high concentration of acceptor impurities will be referred to as a “p+ layer”) in which positive holes act as majority carriers are formed in place of the n+ layer 7a and the n+ layer 7b, if n-type semiconductors are used for the p-layer 1, the p-layer 4, and the p-layer 8 and p-type semiconductors are used for the n-layer 3a and the n-layer 3b, the dynamic flash memory can operate using electrons as carriers during writing.

Carrier behavior and accumulation as well as a cell current during a write operation of the dynamic flash memory according to the first embodiment of the present invention will be described with reference to FIGS. 2A to 2C. First, description will be given of a case in which the majority carriers in the n-layer 3a, the n-layer 3b, the n+ layer 7a, and the n+ layer 7b are electrons, poly Si containing a high concentration of donor impurities (hereinafter poly Si containing a high concentration of donor impurities will be referred to as “n+ poly”) is used, for example, for the gate conductor layer 22 connected to the plate line PL and the gate conductor layer 10 connected to the word line WL, and a p-type semiconductor is used for the third semiconductor layer 8. As shown in FIG. 2A, a MOSFET in the memory cell operates using the following components: the n+ layer 7a that serves as a source, the n+ layer 7b that serves as a drain, the gate insulating layer 9, the gate conductor layer 10 that serves as a gate, and the p-layer 8 that serves as a substrate. For example, 0 V is applied to the p-layer 1, 0 V is applied to the n-layer 3a connected with the control line CDC, 0 V is input to the n+ layer 7a connected with the source line SL, 1.2 V is input to the n+ layer 7b connected with the bit line BL, and −1 V is applied to the gate conductor layer 22 connected with the plate line PL. It is assumed here that a threshold of a MOSFET that uses the pre-writing gate conductor layer 10 as a gate electrode is, for example, 1.2 V when the voltage of the plate line PL is −1 V. Next, if, for example, 1.5 V is input to the gate conductor layer 10 connected with the word line WL, an inversion layer 12 is formed partially just under the gate insulating layer 9 located below the gate conductor layer 10 with a pinch-off point 13 existing in the inversion layer 12. Therefore, the MOSFET having the gate conductor layer 10 operates in a saturation region.

As a result, in the MOSFET having the gate conductor layer 10, an electric field is maximized in a boundary region between the pinch-off point 13 and the n+ layer 7b and an impact ionization phenomenon occurs in the boundary region. As a result of the impact ionization phenomenon, electrons accelerated in a direction from the n+ layer 7a connected with the source line SL to the n+ layer 7b connected with the bit line BL collide with a Si lattice and electron-hole pairs are created by kinetic energy of the accelerated electrons. Due to a concentration gradient, the generated positive holes diffuse in a direction in which a hole concentration is lower. Part of the generated electrons flows to the gate conductor layer 10, but the majority of the electrons flows to the n+ layer 7b connected to the bit line BL. As a result, positive hole groups 11 are accumulated in the p-layer 4 and the p-layer 8.

In the above example, the plate line PL is set at −1 V, and this contributes to preventing a depletion layer from spreading in the p-layer and thereby accumulating positive holes generated by impact ionization as well as to adjusting a threshold voltage of the MOSFET in the memory cell by means of a substrate bias effect.

In the above example, the gate conductor layer 22 is biased with a negative voltage using n+ poly, but an effect similar to application of a negative voltage can be obtained using a material higher in work function than the material of the gate conductor layer 10.

Note that positive hole groups may be generated by passing a gate induced drain leakage (GIDL) current instead of causing the impact ionization phenomenon (see, for example, J. Wan, L. Rojer, A. Zaslavsky, and S. Critoloveanu: “A Compact Capacitor-Less High-Speed DRAM Using Field Effect-Controlled Charge Regeneration,” Electron Device Letters, Vol. 35, No.2, pp. 179-181 (2012)).

FIG. 2B shows positive hole groups 11 existing in the p-layer 4 and the p-layer 8 when the word line WL and the plate line PL become −1 V and biases to the source line SL, the bit line BL, and the control line CDC become 0 V just after writing. The generated positive hole groups 11 are majority carriers in the p-layer 4 and the p-layer 8, but the resulting hole concentration becomes temporarily high in a region of the p-layer 8 and thereby moves the positive hole groups toward the p-layer 4 through diffusion due to the concentration gradient. Furthermore, because a negative potential is applied to the first gate conductor layer 22, the positive hole groups are accumulated in higher concentrations in the vicinity of the first gate insulating layer 5 of the p-layer 4. As a result, the hole concentration in the p-layer 4 becomes higher than the hole concentration in the p-layer 8. Since the p-layer 4 and the p-layer 8 are electrically connected, the p-layer 8, which is a MOSFET substrate that practically has the gate conductor layer 10, is charged to be positively biased. The positive holes in the depletion layer move toward the word line WL, the bit line BL, or the n-layers 3, gradually recombining with electrons, but the threshold voltage of the MOSFET containing the gate conductor layer 10 is reduced due to a positive substrate bias effect produced by the positive holes temporarily accumulated in the p-layer 4 and the p-layer 8. In the present example, the threshold voltage of the MOSFET after writing becomes 0.6 V. Consequently, as shown in FIG. 2C, the threshold voltage of the MOSFET containing the gate conductor layer 10 connected with the word line WL, becomes approximately 0.6 V, which is lower than the pre-writing threshold voltage. This written state is assigned to logical storage data “1.”

With the structure according to the present embodiment, since the p-layer 8 of the MOSFET containing the gate conductor layer 10 connected with the word line WL is electrically connected to the p-layer 4, the capacity capable of accumulating generated positive holes can be changed freely by adjusting the volume of the p-layer 4. That is, to increase retention time, for example, the p-layer 4 can be increased in depth. Therefore, it is required that the bottom of the p-layer 4 is located deeper than the bottom of the insulating layer 8. By increasing impurity concentration in the p-layer 4, the quantity of accumulated holes can be increased as well. Because areas placed in contact with the n-layers 3, the n+ layer 7a, and the n+ layer 7b involved in recombination with electrons can be reduced intentionally compared to the volumes of the locations—the p-layer 4 and the p-layer 8 in this case—in which positive hole carriers are accumulated, recombination with electrons can be curbed and the retention time of accumulated positive holes can be increased. Furthermore, because the positive holes accumulated by the application of a negative voltage to the gate conductor layer 22 are accumulated near an interface of the p-layer 4, which is the second semiconductor layer placed in contact with the gate insulating layer 5, and moreover, because the positive holes can be accumulated in locations away from p-n junctions that can cause electron-hole recombination, which in turn can cause data loss, i.e., away from portions in which the n+ layer 7a and the n+ layer 7b contact the p-layer 8, the positive holes can be accumulated stably. Furthermore, application of a negative potential to the gate conductor layer 22 is also effective in accumulation of positive holes because no depletion layer is formed in the p-layer 4. Thus, the whole substrate bias effect of the memory element is achieved on the substrate serving as the memory element, increasing the memory holding time and expanding a voltage margin of “1” writing.

FIG. 3 shows an example of operation waveforms applied to the bit line BL, the source line SL, the word line WL, the plate line PL, and the control line CDC during the write operation of the memory. From time T1 to time T2, the bit line BL rises from a ground voltage Vss to VBL-W. The ground voltage Vss is, for example, 0 V and VBL-W is, for example, 1.2 V. Voltage VPL of the plate line PL is, for example, −1 V. The reason why a negative potential is applied to the plate line PL is to actively accumulate positive holes generated by a write operation in the p-layer 4 as described above. The application of the negative potential also contributes to a capability to adjust the pre-writing threshold voltage of the MOSFET to a value higher than when VPL=0 V to reduce a leakage current. Next, from time T2 to time T3, the word line WL is raised from a negative voltage of VWL-Pause, e.g., −1 V, to a second voltage VWL-W. The voltage VWL-W is, for example, 1.5 V, which is high enough to turn on the MOSFET in the memory cell and cause a current to flow. This depends on the voltage VPL of the plate line PL, with the required voltage VWL-W increasing when VPL is decreased, and the required voltage VWL-W decreasing when VPL is increased.

Consequently, the MOSFET containing the second gate conductor layer 10 connected with the word line WL operates in a saturation region, making it possible to create a state of high electric fields in the MOSFET, increasing an impact ionization rate, and thereby provide voltage application conditions that allows a substrate current to be generated (for example, Yuan Taur and Tak. H. Ning, “Fundamentals of Modern VLSI Devices” (2021)). When the writing is finished, voltages of terminals return to the voltages that existed before the writing.

In addition to the above example, regarding the conditions of the voltages applied, for example, to the bit line BL, the source line SL, the word line WL, and the plate line PL, assuming that SL is 0 V, a combination of 1.0 V (VBL-W)/−1 V (VPL)/2.0 V (VWL-W), 1.0 V (VBL-W)/−0.5 V (VPL)/1.2 V (VWL-W), 1.5 V (VBL-W)/−1 V (VPL)/2.0 V (VWL-W), or the like may be used. The voltage relationship between the bit line BL and the source line SL may be exchanged. However, if 1.0 V is applied to the bit line BL, 0 V to the source line SL, 2 V to the word line WL, and −1 V to the plate line PL, the threshold will fall during writing, causing the pinch-off point 13 to shift gradually toward the n+ layer 7b, and consequently, the MOSFET may perform a linear operation.

Note that in the waveform diagram shown in FIG. 3, if there is a period during which positive potentials are applied to both the bit line BL and the word line WL, it does not matter which of the lines is increased or decreased in voltage first.

Next, an erase operation mechanism will be described using FIGS. 4A to 4C. FIG. 4A shows a state in which just after the positive hole groups 11 generated by impact ionization in the previous cycle are stored in the p-layer 4 and the p-layer 8 before the erase operation. The voltages of the source line SL, the bit line BL, and the control line CDC are 0 V while the voltages of the word line WL and the plate line PL are −1 V.

As shown in FIG. 4B, during the erase operation, the voltages of the source line SL, the bit line BL, the word line WL, and the control line CDC are set to 0 V. The voltages of the plate line PL is set, for example, to 2 V. As a result, regardless of the value of an initial potential of the p-layer 8, an inversion layer 14 of electrons is formed in an interface between the insulating layer 5 and the p-layer 4. Consequently, positive holes accumulated in the p-layer 4 flow from the p-layer 4 to the inversion layer 14 and recombine with electrons. Some of the positive holes flow to the n-layer 3b, the n+ layer 7a, and the n+ layer 7b as well, and also recombine with electrons. As a result, the positive hole concentrations of the p-layer 4 and the p-layer 8 are reduced with time, and the threshold voltage of the MOSFET becomes higher than when “1” is written and returns to an initial state. Here, for example, if the voltage of the plate line PL is −1 V, the threshold of the MOSFET becomes 1.2 V. Consequently, as shown in FIG. 3C, the MOSFET containing the gate conductor layer 10 connected with the word line WL returns to the initial threshold. The erased state of the dynamic flash memory becomes “0” in terms of the logical storage data.

With the structure according to the present embodiment, during data erasure, compared to during data accumulation, an electron-hole recombination area can be effectively increased. Therefore, a stable state with logic information data of “0” can be provided in a short time, improving operating speed of the dynamic flash memory element. Besides, power consumed for data erasure is approximately equal to the total quantity of holes accumulated in the p-layer 4 and the p-layer 8. Because no other current flows, power consumption can be reduced greatly.

FIG. 5 shows operation waveforms applied to the bit line BL, the source line SL, the word line WL, and the plate line PL during the memory erase operation. At time T7, the plate line PL is raised from VPL to a voltage VPL-E. Here, for example, VPL-Pause is −1 V and VPL-E is 2 V. VPL-E is a voltage high enough for the inversion layer 14 to be formed just under the gate insulating film 5 in contact with the gate conductor layer 22 connected to the plate line PL. As a result, the n-layer 3b and the inversion layer 14 come into contact with each other, increasing the electron-hole recombination area. From time T7, the word line WL rises from a voltage VWL-Pause to the voltage VWL-W. Here, for example, VWL-Pause is −1 V and the voltage VWL-W is 0 V. As a result of these operations, the depletion layer extends further into the p-layer 4 and the p-layer 8, reducing a positive hole accumulation volume and thereby working well for the erase operation.

In data erase methods other than the one taken as an example, regarding the conditions of the voltages applied to the bit line BL, the source line SL, the word line WL, and the plate line PL, assuming that VWL-E is equal to VWL-Pause and the source line SL is 0 V, a combination of 0 V (VBL-E)/2 V (WPL-E)/−1 V (VWL-E), 0.4 V (VBL-E)/2 V (VPL-E)/0.5 V (VWL-E), 1 V (VBL-E)/1.5 V (VPL-E)/0 V (VWL-E), or the like may be used. The conditions of the voltages applied to the bit line BL, the source line SL, the word line WL, and the plate line PL are only an example used in performing a memory erase operation, and other operating conditions that allow a memory erase operations to be performed may be used.

If the insulating layer 2 and the insulating layer 6 are made approximately equal in film thickness to the gate insulating layer 5, when, for example, 1.5 V is applied to the gate conductor layer 22 during data erasure, the n+ layers 7a and 7b can be connected with the n-layer 3a via the inversion layer 14, making it possible to shorten data erase time. Besides, by adjusting the film thicknesses of the gate insulating layer 5 and insulating layers 2 and 6, the voltage applied to the gate conductor layer 22 can be reduced.

Whereas in the waveform diagram shown in FIG. 5, the plate line PL and the word line WL rise or fall with the same timing, even if waveforms are out of phase from each other, there is no problem as long as a positive potential is applied to VPL-E during data erasure.

Next, a read operation of the dynamic flash memory shown in FIGS. 1A and 1B will be described using the waveform diagram shown in FIG. 6. At time T11, the bit line BL rises from a ground voltage Vss to a voltage VBL-R. The ground voltage Vss is, for example, 0 V and VBL-R is, for example, 0.5 V. Next, from time T12 to time T13, by raising the word line WL from VWL-Pause to a voltage VWL-R, it is possible to determine whether information stored in the memory is “1” or “0” based on whether a current larger than a predetermined value flows through the bit line BL. In so doing, VWL-Pause is, for example, −1 V and VBL-R is, for example, 1 V. After the information is read out, at time T14, the word line WL is lowered from the voltage VWL-R to VWL-Pause. Next, from time T15 to time T16, the bit line BL is lowered from the voltage VBL-R to the ground voltage Vss. Note that conditions used in the read operation are that with a voltage applied to the plate line PL, VWL-R is higher than the threshold voltage of the MOSFET during cell writing and lower than the threshold voltage of the MOSFET during erasure.

Note that as can be seen from FIGS. 3, 5, and 6, during standby of the memory, VWL-Pause, e.g., −1 V, is applied to the word line WL; VPL, e.g., −1 V, is applied to the plate line PL; and 0 V is applied to the other lines, namely, the bit line BL, the source line SL, and the control line CDC. In this way, by fixing the potentials of the first gate conductor layer 22 and the second gate conductor layer 10 that affect the p-layer 4 and the p-layer 8, information in the memory cell is protected from external noise signals.

Whereas the control line CDC has been described as being at the ground voltage, i.e., as being set to 0 V during memory writing, erasure, reading, and standby, a positive voltage may be applied to the control line CDC. In particular, by applying a positive voltage to the control line CDC, a p-n junction between the p-layer 4 and the n-layer 3b is reverse-biased, making it hard for the accumulated positive holes from disappearing from the memory cell. The voltage of the control line CDC also allows the threshold of the MOSFET of the memory cell to be adjusted.

According to the present embodiment, the p-layer 8, which is one of the components of the MOSFET that reads and writes information, is electrically connected with the p-layer 1, the n-layers 3, and the p-layer 4. Furthermore, a voltage can be applied to the gate conductor layer 22. Therefore, both in a write operation and erase operation, unlike, for example, an SOI structure, neither the substrate bias becomes unstable in a floating state during operation of the MOSFET nor a semiconductor portion under the gate insulating layer 9 becomes completely depleted. Consequently, the threshold, drive current, and the like of the MOSFET are hardly affected by operational status. Therefore, properties of the MOSFET are such that by adjusting the thickness, impurity type, impurity concentration, and impurity profile of the p-layer 8, the impurity concentration and impurity profile of the p-layer 4, the thickness and material of the gate insulating layer 9, and work functions of the gate conductor layers 10 and 22, voltages relevant to a desired memory operation can be set in a wide range. Because components under the MOSFET are not completely depleted and the depletion layer spreads in a depth direction of the p-layer 4, coupling of a floating body with the gate electrode from a word line, which is a defect of capacitorless DRAMs, almost does not have any impact. That is, the present embodiment allows a wide margin to be provided to operating voltage of the dynamic flash memory.

The present embodiment is effective in preventing malfunctions of memory cells. In memory cell operation, when voltages of a target cell are manipulated, unnecessary voltages are applied to some electrodes of cells other than the target cell in a cell array, resulting in a malfunction, which presents a big problem (for example, T. Shino, N. Kusunoki, T. Higashi, T. Ohsawa, K. Fujita, K. Hatsuda, N. Ikumi, F. Matsuoka, Y. Kajitani, R. Fukuda, Y. Watanabe, Y. Minami, A. Sakamoto, J. Nishimura, H. Nakajima, M. Morikado, K. Inoh, T. Hamamoto, A. Nitayama: “Floating Body RAM Technology and its Scalability to 32 nm Node and Beyond,” IEEE IEDM (2006)). Specifically, such a malfunction involves a phenomenon in which “1” written into a cell is turned to “0” or “0” written into a cell is turned to “1” by other cell operations (hereinafter the phenomenon caused by such a malfunction will be referred to as a “disturbance failure”). According to the present embodiment, when “1” is originally written as data information, the quantity of accumulated holes can be increased by adjusting the depth of the p-layer 4 compared to quantity of electron-hole recombination caused by transistor operation and even under conditions in which conventional memories cause a disturbance failure, threshold fluctuations of the MOSFET are not affected much and thus the MOSFET is less prone to failure. On the other hand, when “0” is originally written as data information, even if unintended positive holes are generated by transistor operation during reading, because the positive holes diffuse quickly in the p-layer 4, if the depth of the p-layer 4 is increased similarly, the rate of change of hole concentration in the entire p-layer 4 and p-layer 8 is low and again, the threshold of the MOSFET is not affected much, and the probability of occurrence of disturbance failure can be reduced more than before. Thus, the present embodiment provides a structure resistant to disturbance failure of memory.

When data information is “0,” because the positive holes generated in the depletion layer during retention and the positive holes making up the electron-hole pairs are accumulated in the p-layer 8, the data may turn from “0” to “1,” but with the structure according to the present invention, because a larger number of positive holes are accumulated in the p-layer 4, changes in the hole concentration in the p-layer 8 is not affected much, and thus “0” data information can be held stably.

According to the present embodiment, because memory can also be erased by applying a positive voltage to the plate line PL at the time of erasure, information in a plurality of cells sharing the gate conductor layer 22 can be erased at once.

As can be seen from the structure shown in FIGS. 1A and 1B, an element structure made up of the p-layer 8, the n+ layers 7a and 7b, the gate insulating layer 9, and the gate conductor layer 10 can be formed not only of the present memory cell, but also in common with a MOS circuit containing a typical CMOS structure other than the present structure. Thus, the present memory cell can be easily combined with conventional CMOS circuits.

Because the memory cell of the present invention is formed in the area of one MOSFET in planar view, by sharing the source line and the bit line with adjacent memory cells, a higher-density memory cell array than conventional dynamic RAMs can be implemented.

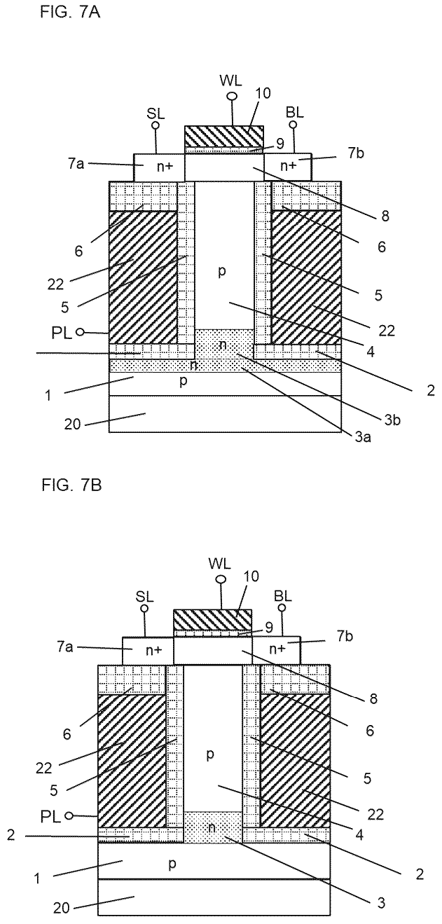

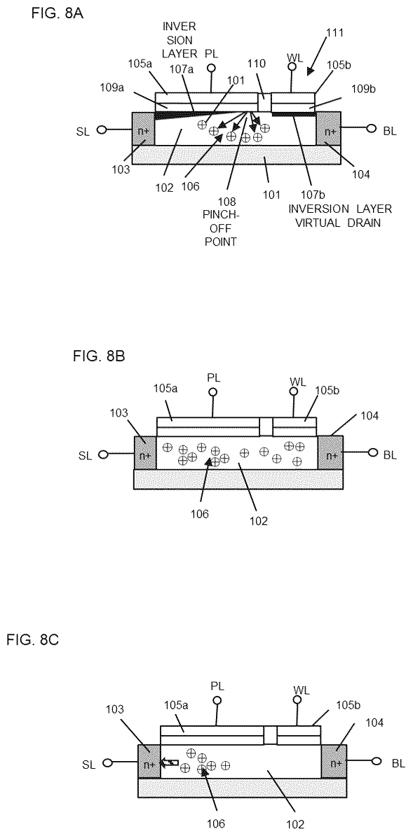

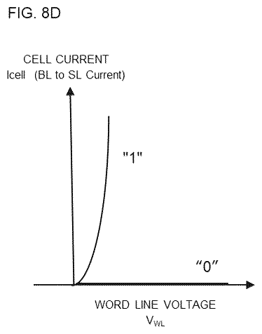

Additional examples of the dynamic flash memory according to the present invention will be described using FIGS. 7A and 7B. In FIGS. 7A and 7B, same or similar components as/to those shown in FIGS. 1A and 1B are denoted by reference signs containing the same numerical symbols as the corresponding components in FIGS. 1A and 1B.

As shown in FIG. 7A, the bottoms of the n-layers 3 in FIGS. 1A and 1B are located shallower than the gate insulating layer 2, and no control line CDC exists. Otherwise, FIG. 7A is the same as FIGS. 1A and 1B. In this case, the gate insulating layer 2 may or may not be in contact with the p-layer 1.

As shown in FIG. 7B, even if each memory cell has an individual n-layer placed on the bottom of the p-layer 4 rather than the n-layer 3 is shared by a plurality of cells, the dynamic flash memory can also operate.

With either of the structures in FIGS. 7A and 7B, by the application of voltages similar to the first embodiment to the source line SL, the plate line PL, the word line WL, and the bit line BL, excluding the control line CDC, the write operation, the erase operation, and the read operation of the dynamic flash memory can be performed.

One of the interconnect structures becomes unnecessary compared to FIGS. 1A and 1B and operation needs slight adjustments, but processes become simple and easy from the viewpoint of manufacturing.

The MOSFET made up of the n+ layers 7a and 7b, the p-layer 8, the gate insulating layer 9, and the gate conductor layer 10 may be a planar MOSFET or a Fin FET. Alternatively, the MOSFET may be an FET including a U-shaped p-layer 8, which is a channel.

Whereas the present embodiment has been described by taking as an example a case in which the p-layers 4 and 8 are formed vertically with respect to the substrate 20, the present invention is also applicable when the p-layers 4 and 8 are formed in a horizontal direction with respect to the substrate 20.

The present embodiment has the following features.

### (Feature 1)

In the dynamic flash memory according to the first embodiment of the present invention, a substrate area on which a MOSFET channel is formed is made up of the p-layer 4 and the p-layer 8 surrounded by the insulating layer 2, the gate insulating layer 5, the n-layers 3, and the n+ layers 7a and 7b. This structure makes it possible to accumulate the majority carriers generated in writing logical data of “1” in the p-layer 8 and the p-layer 4 and increase the number of majority carriers. Furthermore, because the positive holes generated during writing by the application of a negative voltage to the gate conductor layer 22 can be accumulated near the interface of the p-layer 4 in the vicinity of the gate conductor layer 22 and no depletion layer is formed in the p-layer 4, the accumulated quantity of positive holes can be increased and information retention time is extended. During data erasure, as an inversion layer and a depletion layer are formed by the application of a positive voltage to the gate conductor layer 22, effectively increasing the electron-hole recombination area, the recombination area with electrons can be increased and the erasure is done in a short time. This makes it possible to expand the operating margin of the memory and reduce power consumption, resulting in high-speed action of the memory.

### (Feature 2)

The p-layer 8, which is a component of the MOSFET contained in the dynamic flash memory according to the first embodiment of the present invention, is connected with the p-layer 4, the n-layers 3a and 3b, and the p-layer 1, and if the voltage applied to the gate conductor layer 22 is adjusted, the p-layer 8 and the p-layer 4 under the gate insulating layer 9 are not completely depleted and the threshold of the MOSFET can be set freely. Consequently, the threshold, drive current, and the like of the MOSFET are hardly affected by the operational status of the memory. Furthermore, since the components under the MOSFET are not completely depleted, coupling of a floating body with the gate electrode from a word line, which is a defect of capacitorless DRAMs, almost does not have a significant impact. That is, the present invention allows a wide margin to be provided to the operating voltage of the dynamic flash memory.

### (Feature 3)

The p-layer 8, which is a component of the MOSFET contained in the dynamic flash memory according to the first embodiment of the present invention, is connected with the p-layer 4, the quantity of positive holes accumulated when information data of “1” is written can be made 10 times or more larger than, for example, a conventional zero-capacitor DRAM (M. G. Ertosun, K. Lim, C. Park, J. Oh, P. Kirsch, and K. C. Saraswat: “Novel Capacitorless Single-Transistor Charge-Trap DRAM (1T CT DRAM) Utilizing Electron,” IEEE Electron Device Letter, Vol. 31, No.5, pp. 405-407 (2010); and T. Shino, N. Kusunoki, T. Higashi, T. Ohsawa, K. Fujita, K. Hatsuda, N. Ikumi, F. Matsuoka, Y. Kajitani, R. Fukuda, Y. Watanabe, Y. Minami, A. Sakamoto, J. Nishimura, H. Nakajima, M. Morikado, K. Inoh, T. Hamamoto, A. Nitayama: “Floating Body RAM Technology and its Scalability to 32 nm Node and Beyond,” IEEE IEDM (2006)). Therefore, even if disturbance factors affect the voltages applied to the memory cell for purposes other than reading and writing, written information data of “1” is hard to disappear. When information data of “0” is being written into memory, even if disturbance factors affect the voltages applied to the memory cell for purposes other than reading and writing, and positive holes other than intended ones are generated in the memory cell, positive holes in quantities large enough to turn the information into “1” in a short time are not generated. As a result, the present invention is a memory cell structure resistant to disturbance failure.

### (Feature 4)

With the dynamic flash memory according to the first embodiment of the present invention, when a plurality of cells are placed in the n-layer 3 and the gate conductor layer 22 is shared, an erase operation can be performed on a plurality of cells in a single procedure.

### (Feature 5)

With the dynamic flash memory according to the first embodiment of the present invention, because the current that flows during data erasure is limited to about the same level as the total quantity of positive holes accumulated in the memory cell, power consumption is very low.

### (Feature 6)

The dynamic flash memory according to the first embodiment of the present invention provides a structure that has CMOS compatibility with a higher-density memory cell array.

### INDUSTRIAL APPLICABILITY

The use of the semiconductor element according to the present invention provides a semiconductor memory device higher in density, speed, and operating margin than conventional semiconductor memory devices.

What is claimed is:

1. A memory device that uses a semiconductor element, the memory device comprising:
a substrate;
a first semiconductor layer placed on the substrate;
a first impurity layer placed on part of a surface of the first semiconductor layer;
a second impurity layer extending in a vertical direction by being placed in contact with the first impurity layer;
a second semiconductor layer extending in the vertical direction by being placed in contact with a columnar part of the second impurity layer;
a first insulating layer covering part of the first semiconductor layer and part of the second impurity layer;
a first gate insulating layer surrounding the second impurity layer and the second semiconductor layer by being placed in contact with the first insulating layer;
a first gate conductor layer placed in contact with the first insulating layer and the first gate insulating layer;
a second insulating layer formed in contact with the first gate conductor layer and the first gate insulating layer;
a third semiconductor layer placed in contact with the second semiconductor layer;
a second gate insulating layer partially or entirely surrounding an upper part of the third semiconductor layer;
a second gate conductor layer partially or entirely covering an upper part of the second gate insulating layer;
a third impurity layer and a fourth impurity layer placed in contact with a lateral surface of the third semiconductor layer located on an outer side of one end of the second gate conductor layer in a horizontal direction in which the third semiconductor layer extends;
a first interconnecting conductor layer connected to the third impurity layer;
a second interconnecting conductor layer connected to the fourth impurity layer;
a third interconnecting conductor layer connected to the second gate conductor layer;
a fourth interconnecting conductor layer connected to the first gate conductor layer; and
a fifth interconnecting conductor layer connected to the first impurity layer,
wherein a memory write operation is performed by controlling voltages applied to the first interconnecting conductor layer, the second interconnecting conductor layer, the third interconnecting conductor layer, the fourth interconnecting conductor layer, and the fifth interconnecting conductor layer and performing an operation of generating electron groups and positive hole groups in the third semiconductor layer and the second semiconductor layer, by an impact ionization phenomenon or a gate induced drain leakage current using a current passed between the third impurity layer and the fourth impurity layer, an operation of removing the generated electron groups or positive hole groups whichever are minority carriers in the third semiconductor layer and the second semiconductor layer, and an operation of causing part or all of the electron groups or positive hole groups whichever are majority carriers in the third semiconductor layer and the second semiconductor layer to remain in the third semiconductor layer and the second semiconductor layer, and
a memory erase operation is performed by controlling voltages applied to the first interconnecting conductor layer, the second interconnecting conductor layer, the third interconnecting conductor layer, the fourth interconnecting conductor layer, and the fifth interconnecting conductor layer, and extracting the electron groups or the positive hole groups whichever are majority carriers remaining in the second semiconductor layer or the third semiconductor layer from at least one location in the first impurity layer, the second impurity layer, the third impurity layer, and the fourth impurity layer by recombining the electron groups or the positive hole groups with majority carriers in the first impurity layer, the second impurity layer, the third impurity layer, and the fourth impurity layer.

2. The memory device that uses a semiconductor element according to claim 1, wherein the first interconnecting conductor layer connected to the third impurity layer is a source line, the second interconnecting conductor layer connected to the fourth impurity layer is a bit line, the third interconnecting conductor layer connected to the second gate conductor layer is a word line, the fourth interconnecting conductor layer connected to the first gate conductor layer is a plate line, and the fifth interconnecting conductor layer is a control line, and the memory write operation and the memory erase operation are performed by applying voltages to the source line, the bit line, the plate line, the word line, and the control line, respectively.

3. The memory device that uses a semiconductor element according to claim 1, wherein:
during the memory write operation, voltages are applied such that a potential difference is produced between the third and fourth impurity layers, and when majority carriers in the second semiconductor layer are positive holes, a positive voltage is applied to the second gate conductor layer; and
when majority carriers in the second semiconductor layer are electrons, a negative voltage is applied to the second gate conductor layer and a voltage of a different polarity from the second gate conductor layer or a voltage of 0 V is applied to the first gate conductor layer.

4. The memory device that uses a semiconductor element according to claim 1, wherein during the memory erase operation, a voltage of a different polarity from the time when the memory write operation or a voltage of 0 V is applied to the first gate conductor layer.

5. The memory device that uses a semiconductor element according to claim 1, wherein during a memory read operation, a voltage of a same polarity as during the memory write operation or a voltage of 0 V is applied to the first gate conductor layer, and voltages are applied such that a potential difference is produced between the third and fourth impurity layers and a voltage of a same polarity as during the memory write operation is applied to the second gate conductor layer.

6. The memory device that uses a semiconductor element according to claim 1, wherein during a memory wait operation, a voltage of a different polarity from a voltage applied during the memory write operation, or a voltage of 0 V is applied to the first gate conductor layer and the second gate conductor layer.

7. The memory device that uses a semiconductor element according to claim 1, wherein a threshold of a MOS transistor made up of the third semiconductor layer, the second impurity layer, the third impurity layer, the second gate insulating layer, and the second gate conductor layer before operation is adjusted by changing a voltage applied to the first gate conductor layer.

8. The memory device that uses a semiconductor element according to claim 1, wherein majority carriers in the first impurity layer are different form majority carriers in the first semiconductor layer.

9. The memory device that uses a semiconductor element according to claim 1, wherein majority carriers in the second impurity layer are different form majority carriers in the first semiconductor layer.

10. The memory device that uses a semiconductor element according to claim 1, wherein majority carriers in the second semiconductor layer are same as majority carriers in the first semiconductor layer.

11. The memory device that uses a semiconductor element according to claim 1, wherein majority carriers in the third impurity layer and the fourth impurity layer are same as majority carriers in the first impurity layer.

12. The memory device that uses a semiconductor element according to claim 1, wherein the second impurity layer is lower in concentration than the third impurity layer and the fourth impurity layer.

13. The memory device that uses a semiconductor element according to claim 1, wherein a vertical distance from a bottom of the third semiconductor layer to an upper part of the second impurity layer is shorter than a vertical distance from the bottom of the third semiconductor layer to a bottom of the first gate conductor layer.

14. The memory device that uses a semiconductor element according to claim 1, wherein a bottom of the first impurity layer is located deeper than a bottom of the first insulating layer, and the first impurity layer is shared by a plurality of cells.

15. The memory device that uses a semiconductor element according to claim 1, wherein an upper surface of the second impurity layer is located shallower than an upper surface of the first insulating layer.
